(19) United States
(12) Patent Application Publication
(10) Pub. No.: US 2026/0160786 A1
(43) Pub. Date: Jun. 11, 2026

(54) PROBE CARD AND METHOD OF FORMING THE SAME

(71) Applicant: Taiwan Semiconductor Manufacturing Company, Ltd., Hsinchu (TW)

(72) Inventors: Jia Zhen Li, Pingtung County (TW); Kuan Chun Chen, Hsinchu City (TW); Yu-Hsuan Cheng, New Taipei City (TW); Kai-Yi Tang, New Taipei City (TW)

(73) Assignee: Taiwan Semiconductor Manufacturing Company, Ltd., Hsinchu (TW)

(21) Appl. No.: 18/969,302

(22) Filed: Dec. 5, 2024

(51) Int. Cl. G01R 1/073; G01R 1/067

(52) U.S. Cl. CPC G01R 1/07342; G01R 1/0675

(57) ABSTRACT

A probe card includes a force line, a sense line, a force pad, a sense pad and a needle structure. The force pad and the sense pad are electrically connected to the force line and the sense line respectively, wherein the force pad and the sense pad are electrically isolated. The needle structure includes a force needle, a sense needle and an insulating layer. The force needle is electrically connected to the force pad. The sense needle is electrically connected to the sense pad. The insulating layer is disposed between and electrically isolates the force needle and the sense needle.

### BACKGROUND

In semiconductor integrated circuit (IC) manufacturing, wafers are tested during manufacturing and prior to shipment to ensure proper operation. Wafer testing is a testing technique where a temporary electrical connection is established between automatic test equipment (ATE) and dies formed on the wafer to demonstrate proper performance of the ICs.

Along with complexity improvement of circuit designs, rapid development of semiconductor fabrication processes, and demand for circuit performance, ICs have been developed with a three-dimensional (3D) structure to increase circuit performance. New and different test equipment is needed for these 3D structures.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a cross-sectional view of a probe card and a semiconductor device to be tested using the probe card according to some embodiments, and FIG. 1B illustrates a top view of a needle structure, a force pad and a sense pad in a region A of FIG. 1A according to some embodiments.

FIG. 2A illustrates a cross-sectional view of a probe card and a semiconductor device to be tested using the probe card according to some embodiments, and FIG. 2B illustrates a top view of a needle structure, a force pad and a sense pad in a region A of FIG. 2A according to some embodiments.

FIG. 3 illustrates a cross-sectional view of a probe card and a semiconductor device to be tested using the probe card according to some embodiments.

FIG. 4A illustrates a cross-sectional view of a probe card and a semiconductor device to be tested using the probe card according to some embodiments, and FIG. 4B illustrates a top view of a needle structure in a region A of FIG. 4A according to some embodiments.

FIG. 5 illustrates a cross-sectional view of a probe card and a semiconductor device to be tested using the probe card according to some embodiments.

FIG. 6A illustrates a cross-sectional view of a probe card and a semiconductor device to be tested using the probe card according to some embodiments, FIG. 6B illustrates a three-dimensional view of a needle structure of a probe card according to some embodiments, and FIG. 6C illustrates a top view of a needle structure of FIG. 6A according to some embodiments.

FIG. 7A to FIG. 7C illustrate various cross-sectional views of a method of forming a needle structure according to some embodiments.

FIG. 8A to FIG. 8C illustrate various cross-sectional views of a method of forming a needle structure according to some embodiments.

FIG. 9A to FIG. 9D illustrate various cross-sectional views of a method of forming a needle structure according to some embodiments.

FIG. 10A to FIG. 10D illustrate various cross-sectional views of a method of forming a needle structure according to some embodiments.

FIG. 11 illustrates a flowchart of a method of forming a semiconductor device according to some embodiments.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “top” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

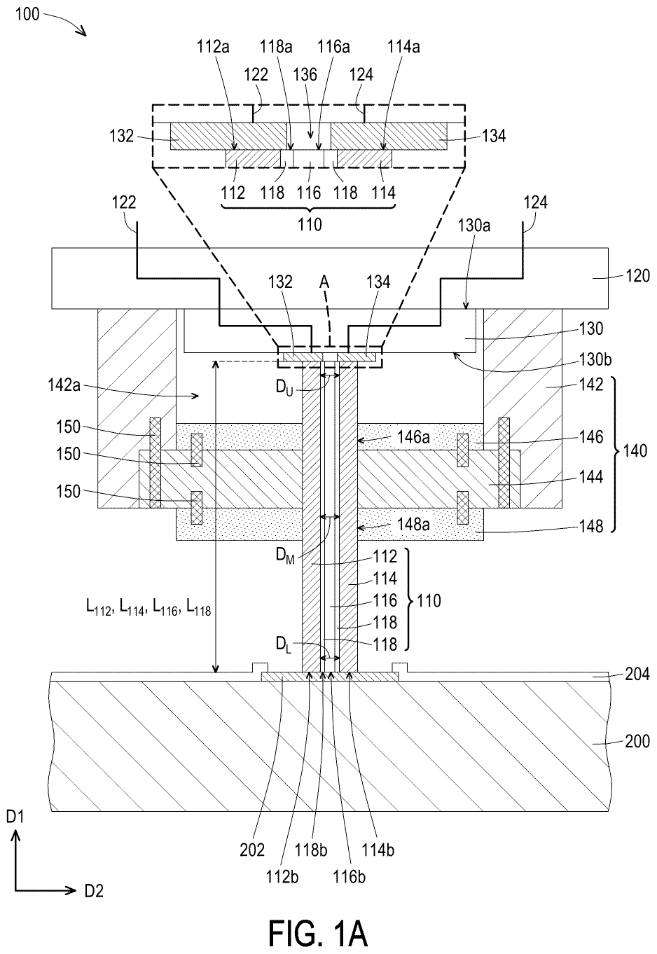

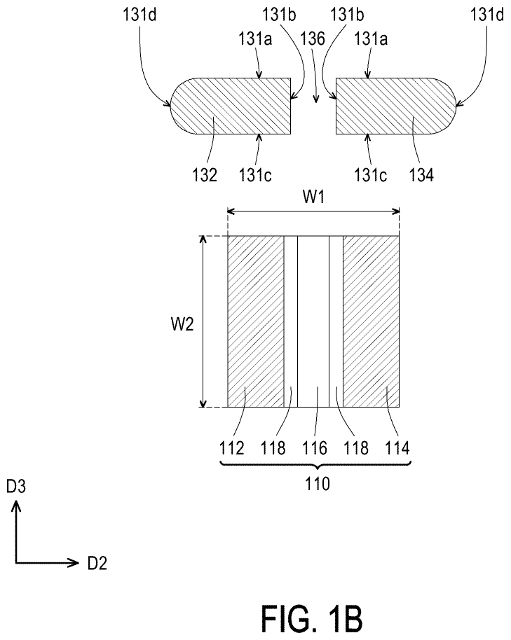

FIG. 1A illustrates a cross-sectional view of a probe card and a semiconductor device to be tested using the probe card according to some embodiments, and FIG. 1B illustrates a top view of a needle structure, a force pad and a sense pad in a region A of FIG. 1A according to some embodiments.

Referring to FIG. 1A, a probe card 100 includes a needle structure 110. The probe card 100 may further include a first wiring substrate 120, a second wiring substrate 130 and a mounting assembly 140. In some embodiments, the needle structure 110 and the mounting assembly 140 may be collectively referred to as a probe head. In some embodiments, the first wiring substrate 120 is a circuit substrate such as a printed circuit board (PCB). The needle structure 110 is mounted on a side (e.g., an underside) of the first wiring substrate 120. As shown in FIG. 1A, the needle structure 110 is a “multi-layer organic substrate (MLO) type” of probe card. For example, in an “MLO type” probe card, the second wiring substrate 130 is disposed between the needle structure 110 and first wiring substrate 120. The second wiring substrate 130 is an interposer. The second wiring substrate 130 is disposed between the mounting assembly 140 and first wiring substrate 120, for example. The second wiring substrate 130 is electrically connected to the first wiring substrate 120 through electrical connectors (not shown) such as solder ball. In some embodiments, the first wiring substrate 120 and the second wiring substrate 130 have a force line 122 and a sense line 124 therein. In other words, each of the force line 122 and the sense line 124 is formed by wires of the first wiring substrate 120 and the second wiring substrate 130. The force line 122 and the sense line 124 are also referred to as power force line and power sense line respectively. In alternative embodiments in which the needle structure 110 is a “hard wire type” probe card, the second wiring substrate 130 may be omitted.

In some embodiments, the needle structure 110 is connected to the mounting assembly 140, and the mounting assembly 140 is connected to the first wiring substrate 120. The mounting assembly 140 may include a plurality of supporting elements such as a jig 142 and a spacer 144 and housing elements such as a first housing element 146 and a second housing element 148. The jig 142 may be attached onto the first wiring substrate 120 through mechanical connectors (not shown) such as screws. The spacer 144 may be assembled with the jig 142 through mechanical connectors 150 such as screws. As shown in FIG. 1A, the jig 142 and the spacer 144 are assembled to form a housing space 142a. For example, the second wiring substrate 130 is disposed in the housing space 142a and between the first wiring substrate 120 and the spacer 144. The second wiring substrate 130 may be surrounded by the jig 142. The first housing element 146 and the second housing element 148 may be attached to opposite sides (e.g., top side and bottom side) of the spacer 144. For example, the first housing element 146 and the second housing element 148 are attached onto the spacer 144 through mechanical connectors 150 such as screws, respectively. In some embodiments, the first housing element 146 is disposed in the housing space 142a over the spacer 144 and is surrounded by the jig 142, and the second housing element 148 is disposed under the spacer 144. The first housing element 146 is disposed between the second wiring substrate 130 and the spacer 142, and the spacer 142 is disposed between the first housing element 146 and the second housing element 148, for example. A material of the jig 142, the spacer 144, the first housing element 146 and the second housing element 148 includes metal, ceramic, plastic or the like. The material of the jig 142, the spacer 144, the first housing element 146 and the second housing element 148 may be different or the same. It is noted that the number and/or the configuration of the supporting elements such as the jig 142 and the spacer 144 and the housing elements such as the first housing element 146 and the second housing element 148 may be adjusted according to the requirements.

In some embodiments, the first housing element 146 and the second housing element 148 respectively have an opening 146a, 148a for the needle structure 110. The needle structure 110 may pass through the openings 146a, 148a to be held by the first housing element 146 and the second housing element 148. The needle structure 110 is disposed in and/or inserted into the openings 146a, 148a of the first housing element 146 and the second housing element 148, such that the needle structure 110 is in direct contact with a force pad 132 and a sense pad 134. The needle structure 110 may be or may be not in direct contact with the first housing element 146 and the second housing element 148. It is noted that the needle structure 110 may be brought into physical contact with the force pad 132 and the sense pad 134 at an underside of the first wiring substrate 120 by any suitable way.

In some embodiments, the needle structure 110 includes a force needle 112, a sense needle 114 and an insulating layer 116. The needle structure 110 includes at least one pair of force needle 112 and sense needle 114, for example, as shown in FIG. 1A, the needle structure 110 includes one pair of the force needle 112 and the sense needle 114. The insulating layer 116 is sandwiched between the force needle 112 and the sense needle 114. The force needle 112, the insulating layer 116 and the sense needle 114 respectively extend along the first direction D1. Thus, the force needle 112, the insulating layer 116 and the sense needle 114 respectively have an elongated shape such as a needle shape, a pillar shape, a column shape or a sheet shape. The force needle 112, the insulating layer 116 and the sense needle 114 are arranged along the second direction D2. The first direction D1 is a vertical direction such as z direction, the second direction D2 substantially perpendicular to the first direction D1 is a horizontal direction such as x direction, and a third direction D3 (shown in FIG. 1B) substantially perpendicular to the first and second directions D1 and D2 is a horizontal direction such as y direction, for example. As shown in FIG. 1A, the needle structure 110 is column-shaped. In a top view, as show in FIG. 1B, the needle structure 110 may be rectangular. A width W1 of the needle structure 110 along the second direction D2 is substantially equal to a width W2 of the needle structure 110 along the third direction D3, for example. However, the disclosure is not limited thereto. In alternative embodiments, the force needle 112 and the sense needle 114 may be also referred to as force pin and sense pine, force-side probe and sense-side probe or the like.

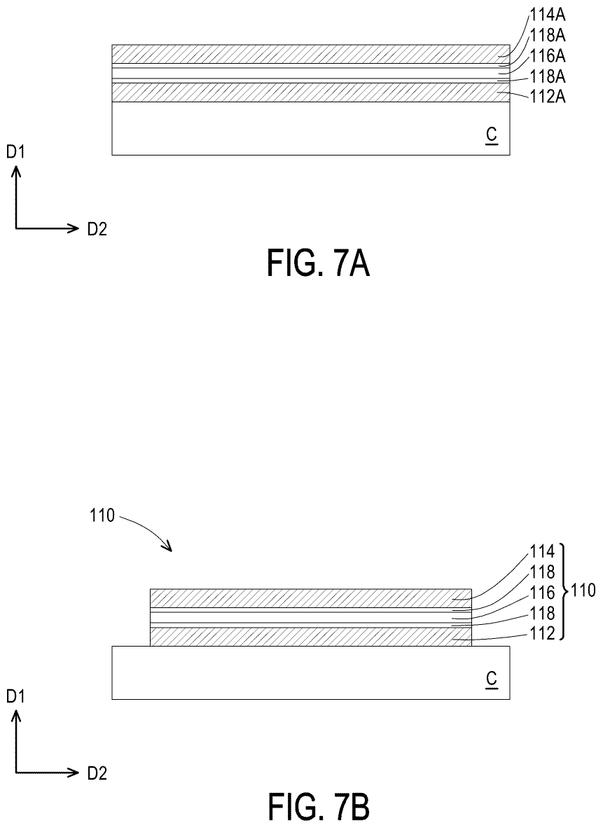

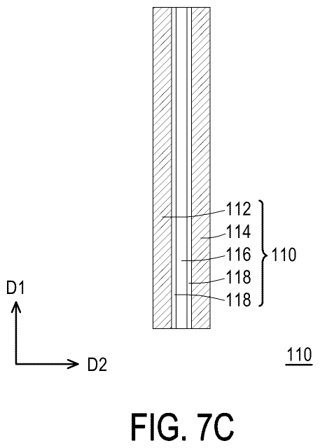

The force needle 112 and the sense needle 114 include a conductive material. The conductive material may be a metal such as Cu, Pd, Rh and Ag, an alloy thereof or the like. The material of the force needle 112 is the same as or different from the material of the sense needle 114. A thickness of the force needle 112 and the sense needle 114 along the second direction D2 is, for example, larger than 5 μm. The insulating layer 116 electrically isolates the force needle 112 and the sense needle 114. A material of the insulating layer 116 includes silicon oxide or aluminum oxide; nitrides such as silicon nitride; carbides such as silicon carbide; a combination thereof such as silicon oxynitride, silicon oxycarbide, silicon carbonitride, silicon oxycarbonitride; or the like. A thickness of the insulating layer 116 along the second direction D2 is, for example, larger than 5 μm. The thickness of the insulating layer 116 is smaller than the thickness of each of the force needle 112 and the sense needle 114. However, the disclosure is not limited thereto. In some embodiments, the needle structure 110 further includes adhesion layers 118 disposed between the force needle 112 and the insulating layer 116 and disposed between the sense needle 114 and the insulating layer 116 respectively. The adhesion layers 118 may improve the adhesion between the force needle 112 and the insulating layer 116 and the adhesion between the sense needle 114 and the insulating layer 116. The adhesion layer 118 includes a conductive material. The conductive material may be a metal such as Pt, Au, Cr, Ti, Al, Ni, W, an alloy thereof or the like. The materials of the adhesion layers 118 are the same or different. A thickness of the adhesion layers 118 along the second direction D2 is, for example, larger than 1 μm. The thickness of the adhesion layer 118 is smaller than the thickness of each of the force needle 112 and the sense needle 114 along the second direction D2. However, the disclosure is not limited thereto. The adhesion layer 118 is also referred to as a conductive glue layer or a barrier layer. The force needle 112, the sense needle 114, the insulating layer 116 and the adhesion layer 118 are respectively a single layer or a multilayer. In some embodiments, the force needle 112 and the sense needle 114 are also referred to as MEMS needles since the force needle 112 and the sense needle 114 may be formed by using the techniques such as lithographic process for the manufacture of the integrated circuits (ICs), which will be described in FIG. 7A to FIG. 9D. The needle structure 110 is also referred to a MEMS (Micro-Electro-Mechanical System) structure, for example. In alternative embodiments, at least one of the adhesion layers 118 is omitted.

In some embodiments, the probe card 100 further includes a force pad 132 and a sense pad 134. For example, the force pad 132 is disposed between and electrically connects the force needle 112 and the force line 122, and the sense pad 134 is disposed between and electrically connects the sense needle 114 and the sense line 124. In some embodiments, the second wiring substrate 130 has a first surface 130a facing the first wiring substrate 120 and a second surface 130b facing the needle structure 110. The force pad 132 and the sense pad 134 are formed at the second surface 130b, for example. For example, the force pad 132 and the sense pad 134 are formed on (e.g., protruding from) the second surface 130b of the second wiring substrate 130 as shown in FIG. 1A or embedded in the second wiring substrate 130 and exposed. The force pad 132 and the sense pad 134 may be formed by a lithography process simultaneously with or after the fabrication of the second wiring substrate 130. The force pad 132 and the sense pad 134 are physically separated, and a gap 136 (e.g., an air gap) is formed between the force pad 132 and the sense pad 134. A width of the gap 136 is smaller than the thickness of the insulating layer 116 along the second direction D2, for example. The width of the gap 136 along the second direction D2 is larger than 5 um, for example. In alternative embodiments, an insulating material fills the gap 136 to be inserted between the force pad 132 and the sense pad 134. In a top view, a shape of the force pad 132 and the sense pad 134 is a polygon, a circle or a combination thereof. For example, as shown in FIG. 1B, the polygon shape of the force pad 132 and the sense pad 134 is a combination of a rectangle and a semi-circle. For example, the force pad 132 and the sense pad 134 respectively have three linear sides 131a, 131b, 131c and one curved side 131d. The linear sides 131a, 131b, 131c of the force pad 132 and the linear sides 131a, 131b, 131c of the sense pad 134 may be facing to each other, and the curved side 131d of the force pad 132 and the curved side 131d of the sense pad 134 may be facing away from each other. In some embodiments, the force pad 132 and the sense pad 134 may have an enlarged size (also an enlarged contact surface) due to the curved side 131d. However, the disclosure is not limited thereto. The force pad 132 and the sense pad 134 may have any suitable shape, and the force pad 132 and the sense pad 134 may have different shapes.

In some embodiments, the force needle 112, the sense needle 114, the insulating layer 116 and the adhesion layer 118 have first surfaces 112a, 114a, 116a, 118a facing the first wiring substrate 110 and second surfaces 112b, 114b, 116b, 118b facing the semiconductor device 200 to be tested. The second surfaces 112b, 114b, 116b, 118b (e.g., bottom surfaces) are opposite to the first surfaces 112a, 114a, 116a, 118a (e.g., top surfaces). The first surfaces 112a, 114a of the force needle 112 and the sense needle 114 may be in direct contact with the force pad 132 and the sense pad 134 respectively. The second surfaces 112b, 114b of the force needle 112 and the sense needle 114 may be in direct contact with an electrical connector 202 on a surface of the semiconductor device 200. The semiconductor device 200 may be positioned on a chuck (not shown). The electrical connector 202 may be a conductive pad with or without solder disposed thereon, a bump or the like. A material of the electrical connector 202 includes a wiring material such as aluminum (Al) alloy or the like. The electrical connector 202 is configured to be power terminal, GND terminal and signal terminal of the semiconductor device 200. In some embodiments, a passivation layer 204 is further formed over the surface of the semiconductor device 200 and exposes a portion of the electrical connector 202. However, the disclosure is not limited thereto. The semiconductor device 200 may have any configurations. In some embodiments, the first surfaces 112a, 114a, 116a, 118a of the force needle 112, the sense needle 114, the insulating layer 116 and the adhesion layer 118 are substantially coplanar, and the second surfaces 112b, 114b, 116b, 118b of the force needle 112, the sense needle 114, the insulating layer 116 and the adhesion layer 118 are substantially coplanar. Thus, a total length L₁₁₂ of the force needle 112, a total length L₁₁₄ of the sense needle 114, a total length L₁₁₆ of the insulating layer 116 and a total length L₁₁₈ of the adhesion layer 118 along the first direction D1 are substantially the same, for example. In some embodiments, the insulating layer 116 is continuously disposed between the force needle 112 and the sense needle 114. For example, the insulating layer 116 is continuously disposed between and electrically isolates upper portions, middle portions and lower portions of the force needle 112 and the sense needle 114. As shown in FIG. 1A, a distance D_{U} between the upper portions of the force needle 112 and the sense needle 114 may be substantially equal to a distance D_{L} between the lower portions of the force needle 112 and the sense needle 114 and a distance D_{M} between the middle portions of the force needle 112 and the sense needle 114 along the second direction D2, respectively. However, the disclosure is not limited thereto.

The first wiring substrate 120 may generate, or be connected to other circuitry that generates, control signals, data signals, clock signals, and/or power signals that may be transmitted to the semiconductor device 200 to be tested. For example, the first wiring substrate 120 is further connected to a test head including a computer system, such as a processor that is coupled to a memory and configured to perform testing of the semiconductor device 200 when the processor executes instructions stored in the memory. When the force needle 112 and the sense needle 114 of the needle structure 110 are brough into physical contact with the electrical connector 202 on the semiconductor device 200 such as 3D integrated circuit package being tested, electrical signals from the test head pass through the first wiring substrate 120, the second wiring substrate 130 and the needle structure 110 into the semiconductor device 200 being tested to perform testing of the semiconductor device 200. Because the voltage and/or current from the electrical connector 202 to the semiconductor device encounters IR drop, the semiconductor device 200 may receive inaccurate voltage and/or current. A sense needle 114 acts like a multi-meter to measure the voltage and/or current at the force needle 112 from the electrical connector 202 to the semiconductor device 202. This measurement is then fed back to the electrical connector 202, allowing it to evaluate and apply the necessary compensation. For example, the force needle 112 is configured to provide the power to the semiconductor device 200, and the sense needle 114 is configured to provide the information (e.g., voltage drop) from the semiconductor device 200 to the test head to adjust the voltage and/or current as a compensation. In some embodiments, the force needle 122 and the sense needle 124 are physically separated, and the force pad 132 for the force needle 122 and the sense pad 134 for the sense needle 124 are physically separated. Thus, the sense needle 124 may contact the electrical connector 202 on the semiconductor device 200 directly and independently from the force needle 122. Accordingly, the sense accuracy may be improved.

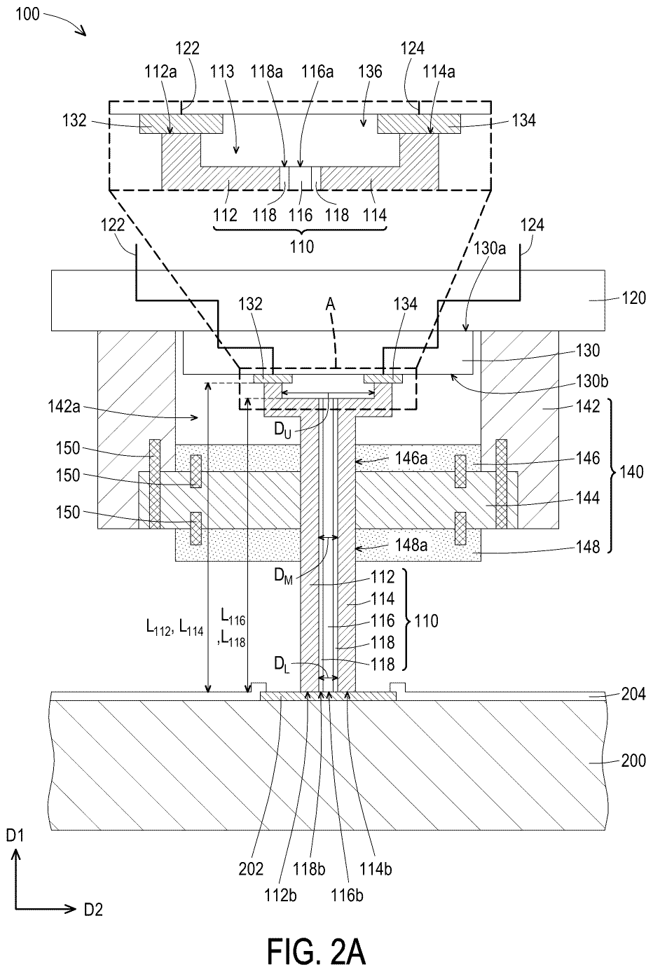

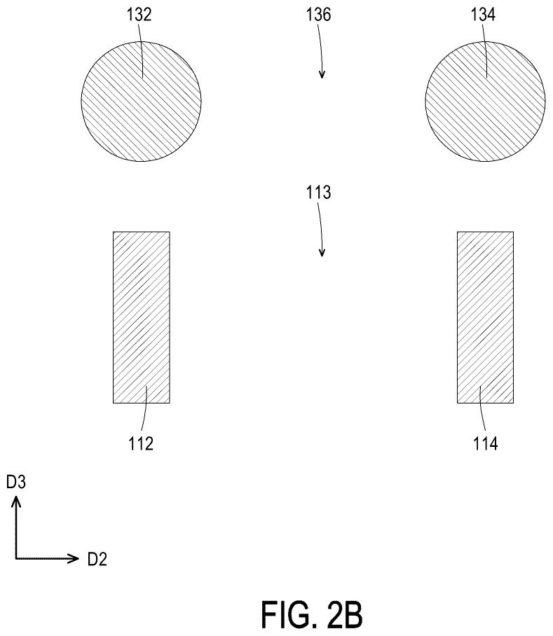

FIG. 2A illustrates a cross-sectional view of a probe card and a semiconductor device to be tested using the probe card according to some embodiments, and FIG. 2B illustrates a top view of a needle structure, a force pad and a sense pad in a region A of FIG. 2A according to some embodiments.

Referring to FIG. 2A, the probe card 100 is similar to that of FIG. 1A, and the difference lies in that the needle structure 110 is fork-shaped. In some embodiments, the force needle 112 and the sense needle 114 include portions extended beyond the insulating layer 116 and the adhesion layer 118 along the first direction D1. In some embodiments, the force needle 112, the sense needle 114, the insulating layer 116 and the adhesion layer 118 have first surfaces 112a, 114a, 116a, 118a facing the first wiring substrate 120 (e.g., also facing the force pads 132-1, 132-2 and the sense pads 134-1, 134-2) and second surfaces 112b, 114b, 116b, 118b facing the semiconductor device 200 to be tested. The first surfaces 112a, 114a of the force needle 112 and the sense needle 114 may be in direct contact with the force pad 132 and the sense pad 134 respectively. In some embodiments, the first surface 116a of the insulating layer 116 is disposed between the first surfaces 112a, 114a and the second surfaces 112b, 114b of the force needle 112 and the sense needle 114. For example, as shown in FIG. 2A, the first surface 116a of the insulating layer 116 is disposed under the first surfaces 112a, 114a of the force needle 112 and above the second surfaces 112b, 114b of the force needle 112 and the sense needle 114. The total length L₁₁₆ of the insulating layer 116 and also the total length L₁₁₈ of the adhesion layer 118 may be smaller than the total length L₁₁₂ of the force needle 112 and the total length L₁₁₄ of the sense needle 114 along the first direction D1, respectively. In some embodiments, the extending portions (e.g., upper portions) of the force needle 112 and the sense needle 114 are electrically isolated by a gap (e.g., air gap) 113 while other portions (e.g., lower portions and middle portions) of the force needle 112 and the sense needle 114 are electrically isolated by the insulating layer 116. Due to the forked shape of the needle structure 110, a distance D_{U} between the extending portions (e.g., upper portions) of the force needle 112 and the sense needle 114 may be larger than a distance D_{L}, D_{M} between other portions (e.g., lower portions and middle portions) of the force needle 112 and the sense needle 114. However, the disclosure is not limited thereto.

In a top view, as shown in FIG. 2B, a shape of the force pad 132 and the sense pad 134 is a circle, a polygon or a combination thereof. For example, the shape of the force pad 132 and the sense pad 134 is respectively a circle since the force pad 132 and the sense pad 134 are physically separated by a larger gap 113 compared to that of FIG. 1B. A width of the gap 136 is substantially equal to the gap 113 (e.g., the distance D_{U}) between the extending portions (e.g., upper portions) of the force needle 112 and the sense needle 114 along the second direction D2, for example. However, the disclosure is not limited thereto. The force pad 132 and the sense pad 134 may have any suitable shapes. In alternative embodiments, an insulating material fills the gap 136 and/or the gap 113 to be inserted between the force pad 132 and the sense pad 134 and/or the extending portions (e.g., upper portions) of the force needle 112 and the sense needle 114.

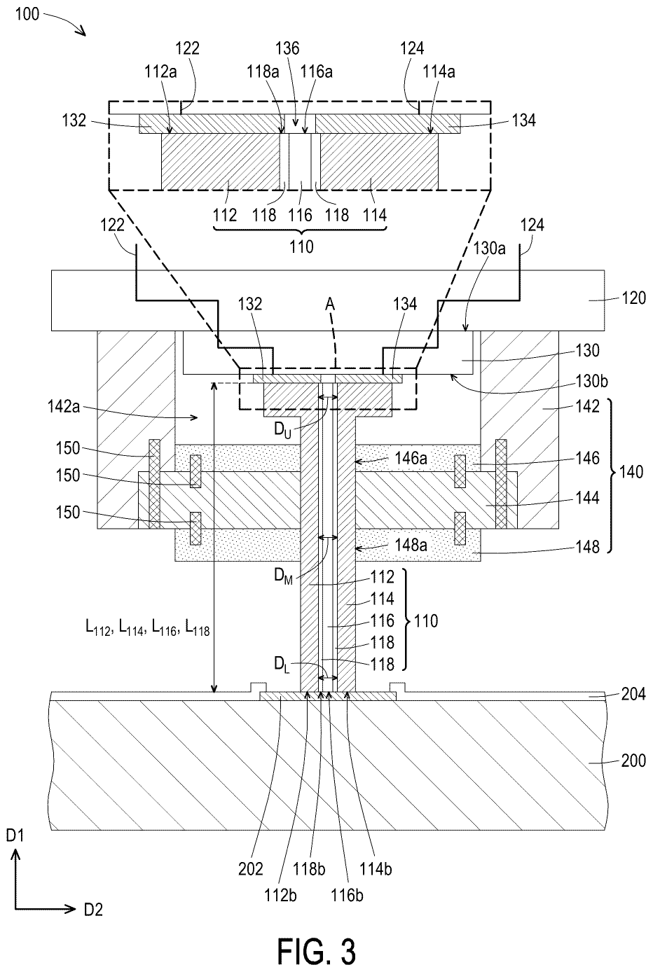

FIG. 3 illustrates a cross-sectional view of a probe card and a semiconductor device to be tested using the probe card according to some embodiments. Referring to FIG. 3, the probe card 100 is similar to that of FIG. 1A, and the difference lies in that the needle structure 110 is T-shaped. For example, in the force needle 112 and the sense needle 114, the upper portions (e.g., separated by the distance D_{U}) are larger than the middle portions (e.g., separated by the distance D_{M}) and the lower portions (e.g., separated by the distance D_{L}). In such embodiments, the first surfaces 112a, 114a, 116a, 118a of the force needle 112, the sense needle 114, the insulating layer 116 and the adhesion layer 118 are substantially coplanar, and the second surfaces 112b, 114b, 116b, 118b of the force needle 112, the sense needle 114, the insulating layer 116 and the adhesion layer 118 are substantially coplanar. The total length L₁₁₂ of the force needle 112, a total length L₁₁₄ of the sense needle 114, the total length L₁₁₆ of the insulating layer 116 and the total length L₁₁₈ of the adhesion layer 118 along the first direction D1 are substantially the same, for example.

In above embodiments, the needle structure 110 has one force needle 112 and one sense needle 114. However, the disclosure is not limited thereto.

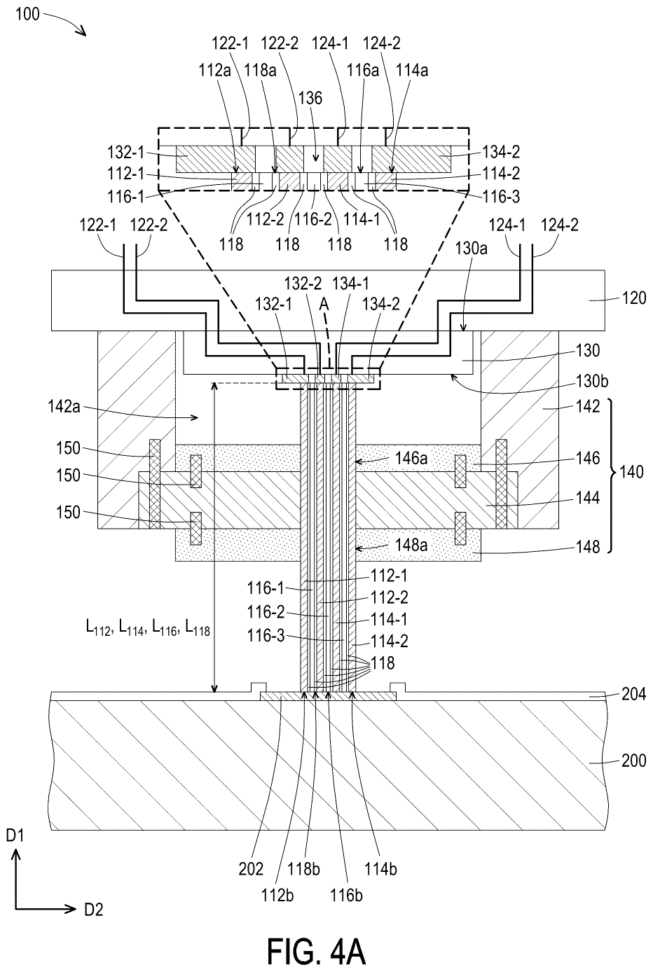

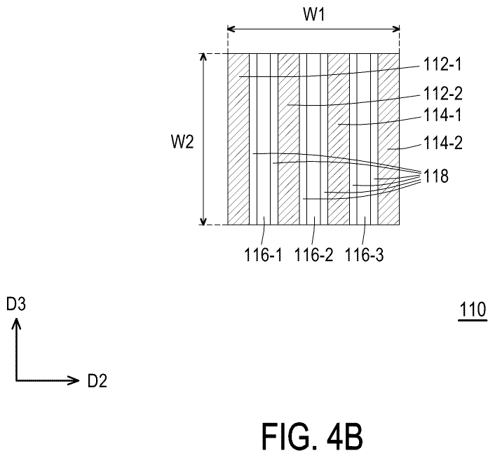

FIG. 4A illustrates a cross-sectional view of a probe card and a semiconductor device to be tested using the probe card according to some embodiments, and FIG. 4B illustrates a top view of a needle structure in a region A of FIG. 4A according to some embodiments.

Referring to FIG. 4A, the probe card 100 is similar to that of FIG. 1A, and the difference lies in that the needle structure 110 has a plurality of force needles 112-1, 112-2 and a plurality of sense needles 114-1, 114-2. In some embodiments, the probe card 100 includes the needle structure 110 including the force needles 112-1, 112-2 and the sense needles 114-1, 114-2, a plurality of force pads 132-1, 132-2, a plurality of sense pads 134-1, 134-2, a plurality of force lines 122-1, 122-2 and a plurality of sense lines 124-1, 124-2. The force needles 112-1, 112-2 and the sense needles 114-1, 114-2 extend along the first direction D1 respectively, and the force needles 112-1, 112-2 and the sense needles 114-1, 114-2 are arranged and interleaved by insulating layers 116-1, 116-2, 116-3 along the second direction D2. For example, as shown in FIG. 4A and FIG. 4B, the force needle 112-1, the force needle 112-2, the sense needle 114-1 and the sense needle 114-2 are arranged sequentially along the second direction D2 and electrically isolated from one another by the insulating layers 116-1, 116-2, 116-3. An adhesion layer 118 is optionally disposed between the insulating layer 116-1, 116-2, 116-3 and the force needle 112-1, 112-2 and between the insulating layer 116-1, 116-2, 116-3 and the sense needle 114-1, 114-2. In some embodiments, as shown in FIG. 4B, a total width W1 of the needle structure 110 along the second direction D2 is substantially equal to a width W2 of the needle structure 110 along the third direction D3, for example. However, the disclosure is not limited thereto.

The force pads 132-1, 132-2 and the sense pads 134-1, 134-2 and the force lines 122-1, 122-2 and the sense lines 124-1, 124-2 may be disposed corresponding to the force needles 112-1, 112-2 and the sense needles 114-1, 114-2. For example, the force pad 132-1, the force pad 132-2, the sense pad 134-1 and the sense pad 134-2 are arranged sequentially along the second direction D2 and electrically isolated from one another, and the force line 122-1, the force line 122-2, the sense line 124-1 and the sense line 124-2 are arranged sequentially along the second direction D2 and electrically isolated from one another. In some embodiments, the first surfaces 112a, 114a, 116a, 118a of the force needles 112-1, 112-2, the sense needles 114-1, 114-2, the insulating layers 116-1, 116-2, 116-3 and the adhesion layers 118 are substantially coplanar, and the second surfaces 112b, 114b, 116b, 118b of the force needles 112-1, 112-2, the sense needles 114-1, 114-2, the insulating layers 116-1, 116-2, 116-3 and the adhesion layers 118 are substantially coplanar. The first surfaces 112a, 114a of the force needles 112-1, 112-2 and the sense needles 114-1, 114-2 directly contact the force pads 132-1, 132-2 and the sense pads 134-1, 134-2 respectively, for example. The force needles 112-1, 112-2, the sense needles 114-1, 114-2, the force pads 132-1, 132-2, the sense pads 134-1, 134-2, the force lines 122-1, 122-2 and the sense lines 124-1, 124-2 may have any suitable arrangement and configurations as long as the force needles 112-1, 112-2 are electrically connected to the force pads 132-1, 132-2 and the force lines 122-1, 122-2 and the sense needles 114-1, 114-2 are electrically connected to the sense pads 134-1, 134-2 and the sense lines 124-1, 124-2.

In some embodiments, the force needle 112-1 is electrically connected to the force line 122-1 through the force pad 132-1, the force needle 112-2 is electrically connected to the force line 122-2 through the force pad 132-2, the sense needle 114-1 is electrically connected to the sense line 124-1 through the sense pad 134-1, and the sense needle 114-2 is electrically connected to the sense line 124-2 through the sense pad 134-2. The force needles 112-1, 112-2 and the sense needles 114-1, 114-2 are electrically isolated from one another by the insulating layers 116-1, 116-2, 116-3 therebetween. For example, the force needle 112-1 and the force needle 112-2 are electrically isolated from each other by the insulating layer 116-1, the force needle 112-2 and the sense needle 114-1 are electrically isolated from each other by the insulating layer 116-2, and the sense needle 114-1 and the sense needle 114-2 are electrically isolated from each other by the insulating layer 116-3. Thus, the measurements of the force needle 112-1, the force needle 112-2, the sense needle 114-1 and the sense needle 114-2 may be performed separately. In some embodiments, multiple insulating layers 116-1, 116-2, 116-3 are respectively sandwiched between adjacent two of the force needles 112-1, 112-2 and the sense needles 114-1, 114-2, and thus the needle structure 110 is also referred to as a multiple-sandwich MEMS structure. In such embodiments, a four-wire measurement at a single needle structure may be achieved.

In some embodiments, the needle structure 110 includes the force needles 112 and the sense needles 114 interleaved by the insulating layers 116-1, 116-2, 116-3, and thus the force needles 112 and the sense needles 114 are electrically isolated from one another. Accordingly, the measurements based on the force needles 112 and the sense needles 114 may be performed independently, and the sense accuracy may be further improved.

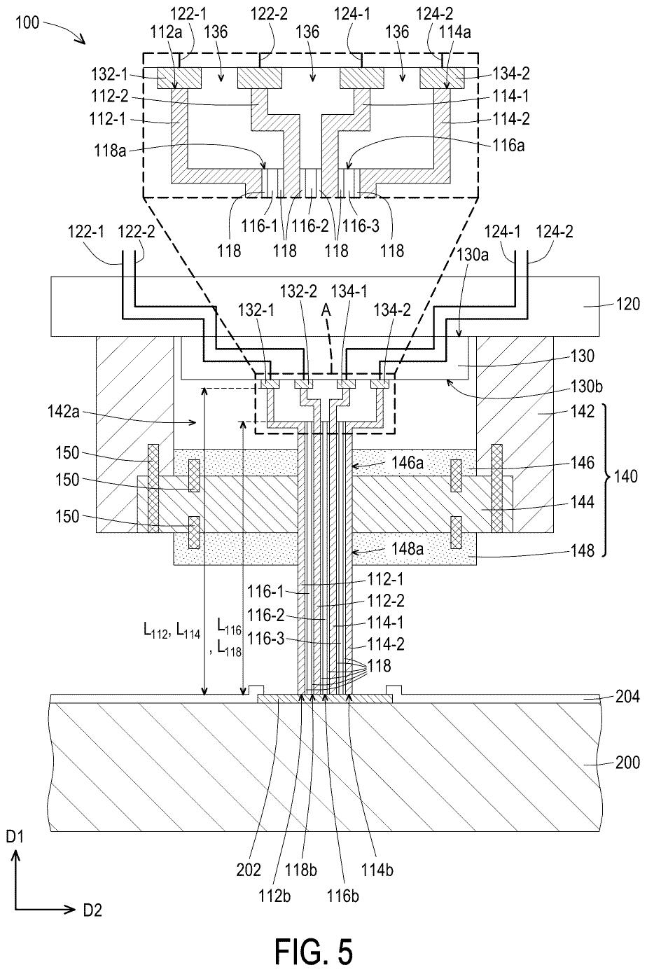

FIG. 5 illustrates a cross-sectional view of a probe card and a semiconductor device to be tested using the probe card according to some embodiments.

Referring to FIG. 5, the probe card 100 is similar to that of FIG. 4A, and the difference lies in that the force needles 112-1, 112-2 and the sense needles 114-1, 114-2 include portions extended beyond the insulating layers 116-1, 116-2. 116-3 and the adhesion layers 118 along the first direction D1. The portions of the force needles 112-1, 112-2 and the sense needles 114-1, 114-2 may be also referred to as extending portions. A width of the extending portions of the force needles 112-1, 112-2 is substantially equal to or smaller than a width of other portions of the force needles 112-1, 112-2 along the second direction D2, and a width of the extending portions of the sense needles 114-1, 114-2 is substantially equal to or smaller than a width of other portions of the sense needles 114-1, 114-2 along the second direction D2. The extending portions of the force needles 112-1, 112-2 and the sense needles 114-1, 114-2 may be arranged in a fan-out configuration, such that the arrangement and/or configuration of the force pads 132-1, 132-2 and the sense pads 134-1, 134-2 may be more flexibly. For example, compared to FIG. 4A, the size (also the contact area) of the force pads 132-1, 132-2 and the sense pads 134-1, 134-2 and/or the gap between the force pads 132-1, 132-2 and the sense pads 134-1, 134-2 is enlarged. Thus, a shape of the force pads 132-1, 132-2 and the sense pads 134-1, 134-2 may be a circle. However, the disclosure is not limited thereto. The shape of the force pads 132-1, 132-2 and the sense pads 134-1, 134-2 may be also a polygon or any other suitable shape. The extending portions may be formed integrally with or separately from other portions of the force needles 112-1, 112-2 and the sense needles 114-1, 114-2, and thus a material of the extending portions may be the same as or different from other portions of the force needles 112-1, 112-2 and the sense needles 114-1, 114-2.

In some embodiments, the first surface 116a of the insulating layers 116-1, 116-2. 116-3 is disposed between the first surfaces 112a, 114a and the second surfaces 112b, 114b of the force needles 112-1, 112-2 and the sense needles 114-1, 114-2. For example, as shown in FIG. 5, the first surface 116a of the insulating layers 116-1, 116-2. 116-3 is disposed under the first surfaces 112a, 114a of the force needles 112-1, 112-2 and above the second surfaces 112b, 114b of the force needles 112-1, 112-2 and the sense needles 114-1, 114-2. The total length L₁₁₆ of the insulating layers 116-1, 116-2. 116-3 and also the total length L₁₁₈ of the adhesion layers 118 may be smaller than the total length L₁₁₂ of the force needles 112-1, 112-2 and the total length L₁₁₄ of the sense needles 114-1, 114-2 along the first direction D1, respectively. In some embodiments, the extending portions (e.g., upper portions) of the force needles 112-1, 112-2 and the sense needles 114-1, 114-2 are electrically isolated by a gap (e.g., air gap) while other portions (e.g., lower portions and middle portions) of the force needles 112-1, 112-2 and the sense needles 114-1, 114-2 of the force needles 112-1, 112-2 and the sense needles 114-1, 114-2 are electrically isolated by the insulating layers 116-1, 116-2. 116-3. In some embodiments, a distance between the extending portions (e.g., upper portions) of the force needles 112-1, 112-2 and the sense needles 114-1, 114-2 may be larger than a distance between other portions (e.g., lower portions and middle portions) of the force needles 112-1, 112-2 and the sense needles 114-1, 114-2 of the force needles 112-1, 112-2 and the sense needles 114-1, 114-2 are electrically isolated by the insulating layers 116-1, 116-2. 116-3. However, the disclosure is not limited thereto.

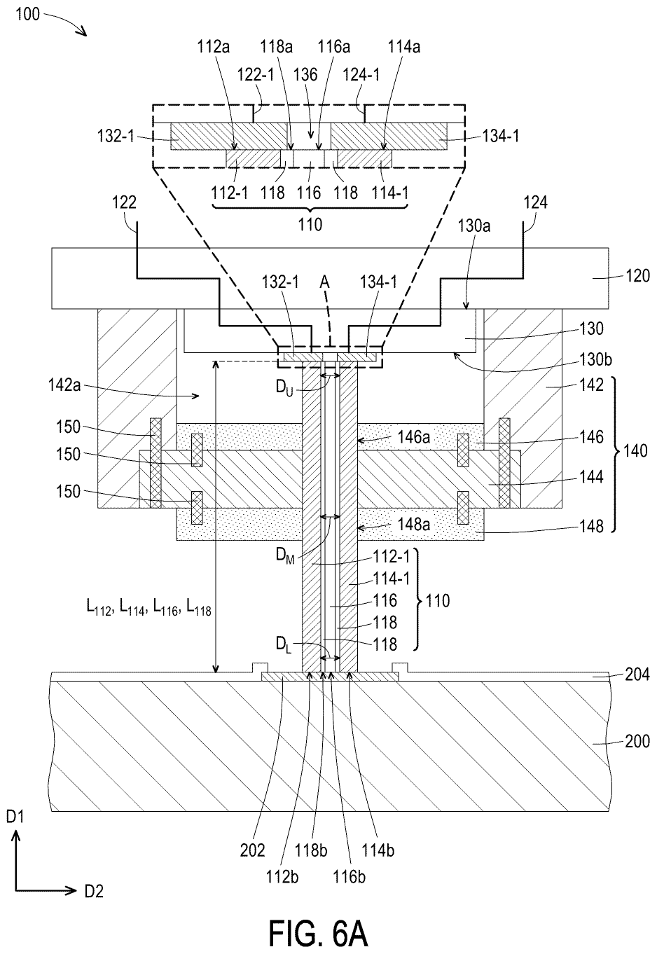

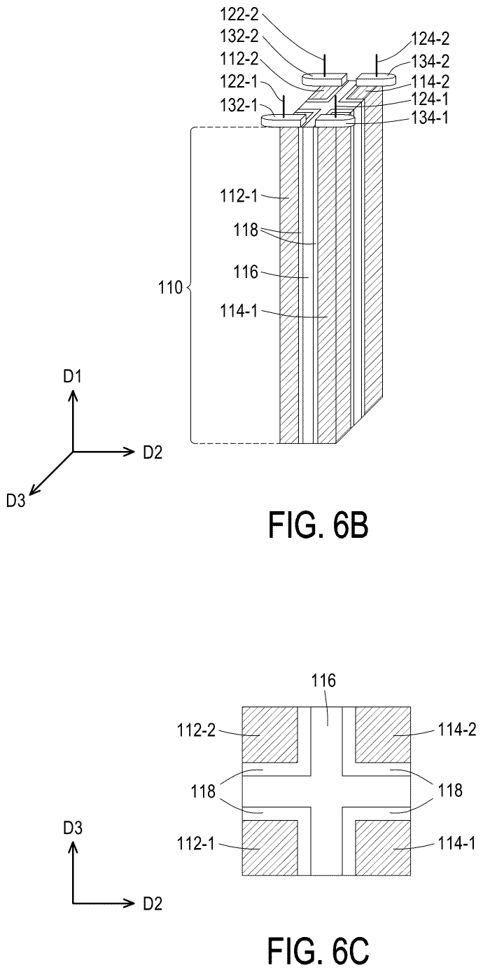

FIG. 6A illustrates a cross-sectional view of a probe card and a semiconductor device to be tested using the probe card according to some embodiments, FIG. 6B illustrates a three-dimensional view of a needle structure of a probe card according to some embodiments, and FIG. 6C illustrates a top view of a needle structure of FIG. 6A according to some embodiments.

Referring to FIG. 6A and FIG. 6B, a needle structure 110 has a plurality of force needles 112-1, 112-2, a plurality of sense needles 114-1, 114-2 and an insulating layer 116. In some embodiments, the insulating layer 116 (e.g., single insulating layer 116) is continuously disposed between each two of the force needles 112-1, 112-2 and the sense needles 114-1, 114-2, and thus the force needles 112-1, 112-2 and the sense needles 114-1, 114-2 are electrically isolated from one another by the insulating layer 116. For example, as shown in FIG. 6B and FIG. 6C, the force needles 112-1, 112-2 and the sense needles 114-1, 114-2 are arranged in an array (e.g., 2×2 array) along the second direction D2 and the third direction D3. In some embodiments, as shown in FIG. 6C, the insulating layer 116 is cross-shaped in a top view and physically separates each two of the force needles 112-1, 112-2 and the sense needles 114-1, 114-2. An adhesion layer 118 may be disposed between the insulating layer 116 and the force needle 112-1, 112-2 and between the insulating layer 116 and the sense needles 114-1, 114-2 respectively, to surround the insulating layer 116. For example, four adhesion layers 118 are disposed to surround the single insulating layer 116. In some embodiments, the force pads 132-1, 132-2 and the sense pads 134-1, 134-2 and the force lines 122-1, 122-2 and the sense lines 124-1, 124-2 may be disposed corresponding to the force needles 112-1, 112-2 and the sense needles 114-1, 114-2. For example, the force pads 132-1, 132-2 and the sense pads 134-1, 134-2 are arranged in an array to electrically connect the force needles 112-1, 112-2 and the sense needles 114-1, 114-2 respectively and to electrically connect the force lines 122-1, 122-2 and the sense lines 124-1, 124-2 respectively. As shown in FIG. 6B, a shape of the force pads 132 and the sense pads 134 is a polygon, a circle or a combination thereof. For example, the force pads 132 and the sense pads 134 have the polygon shape which is similar to that of the force pad 132 and the sense pad 134 in FIG. 1B. However, the disclosure is not limited thereto. The force pads 132 and the sense pads 134 may have any suitable arrangement and/or shape.

In above embodiments of FIG. 1A to FIG. 6C, at least one of the adhesion layers 118 may be omitted.

FIG. 7A to FIG. 7C illustrate various cross-sectional views of a method of forming a needle structure according to some embodiments.

Referring to FIG. 7A, a conductive material 112, an insulating material 116 and a conductive material 114 are sequentially formed over a carrier substrate C. For example, the conductive material 112A is formed on the carrier substrate C, and an adhesion material 118A is formed on the conductive material 112A. Then, the insulating material 116A is formed on the adhesion material 118A over the conductive material 112A, and an adhesion material 118A is formed on the insulating material 116A, for example. After that, the conductive material 114A is formed on the adhesion material 118A over the insulating material 116A, for example. The conductive material 112A, 114A may include a metal such as Cu, Pd, Rh and Ag, an alloy thereof or the like, and the conductive material 112A, 114A may be formed by CVD, ALD, PVD, an electro-chemical plating process, the like, or combinations thereof. The insulating material 116A may include silicon oxide or aluminum oxide; nitrides such as silicon nitride; carbides such as silicon carbide; a combination thereof such as silicon oxynitride, silicon oxycarbide, silicon carbonitride, silicon oxycarbonitride; or the like, and the insulating material 116A may be formed by CVD, ALD, PVD, the like, or combinations thereof. The adhesion material 118A may include a metal such as Pt, Au, Cr, Ti, Al, Ni, W, an alloy thereof or the like, and the adhesion material 118A may be formed by CVD, ALD, PVD, an electro-chemical plating process, the like, or combinations thereof. In alternative embodiments, at least one of the adhesion materials 118A is omitted.

Referring to FIG. 7B, a stack of the conductive materials 112A, 114A and the insulating material 116A is patterned, to form a needle structure 110. In some embodiments, a stack of the conductive materials 112A, 114A, the insulating material 116A and the adhesion materials 118A is patterned by using a lithography process with a mask, to form the needle structure 110. The needle structure 110 may include a force needle 112, an insulating layer 116, a sense needle 114 and optional adhesion layers 118 between the force needle 112 and the insulating layer 116 and between the sense needle 114 and the insulating layer 116.

Referring to FIG. 7C, the needle structure 110 is removed from the carrier substrate C. For example, the needle structure 110 is detached from the carrier substrate C by any suitable process. Then, the needle structure 110 is assembled with the mounting assembly 140 to form a probe head by placing/inserting the needle structure 110 into the openings 146a, 148a of the first housing element 146 and the second housing element 148. After that, the assembled structure is then attached to the first wiring substrate 120 and the second wiring substrate 130, to form the probe card 100 of FIG. 1A. In some embodiments, the needle structure 110 and the probe card 100 are similar to those described in FIG. 1A and FIG. 1B, so the detailed description thereof is omitted herein.

In above embodiments, the needle structure 110 is formed by stacking the materials of the needle structure 110 and patterning the stacked materials. However, the disclosure is not limited thereto. The needle structure 110 may be formed by any suitable processes used for the manufacture of the integrated circuits. In some embodiments, the needle structure 110 of FIG. 1A is formed by forming a conductive material and replacing a middle portion of the conductive material with the insulating layer, and thus the force needle 112, the sense needle 114 and the insulating layer 116 therebetween are formed.

In some embodiments, the force needle 112 and the sense needle 114 may be formed by using the techniques such as lithographic process for the manufacture of the integrated circuits (ICs), and thus the force needle 112 and the sense needle 114 are also referred to as MEMS needles, and the needle structure 110 is also referred to as a MEMS structure. Due to the use of such lithographic process, it is possible to form a number of needle structures having sufficiently homogeneous structural and electrical features in a relatively economical way.

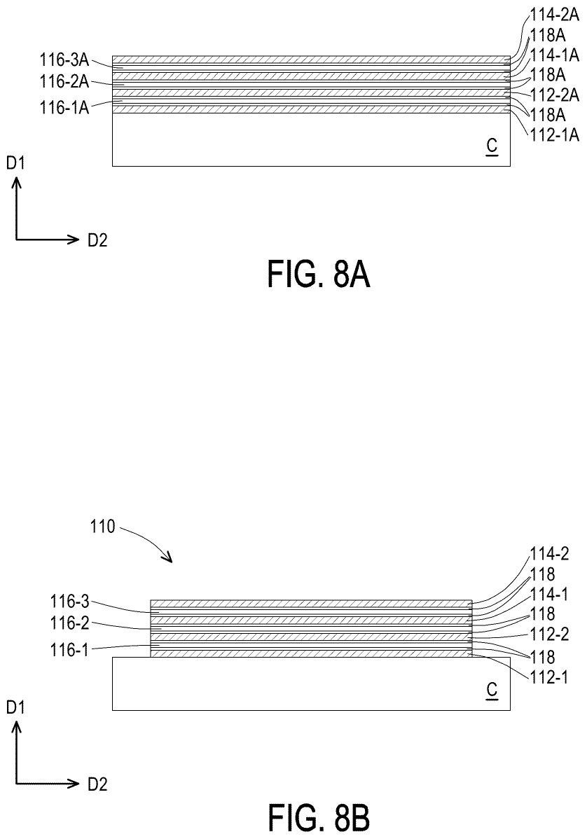

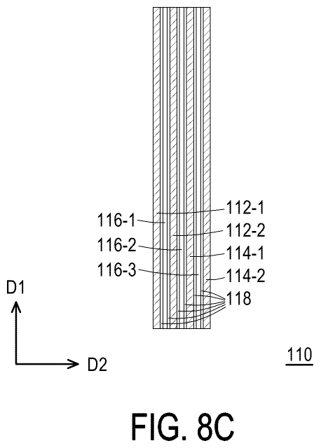

FIG. 8A to FIG. 8C illustrate various cross-sectional views of a method of forming a needle structure according to some embodiments.

Referring to FIG. 8A, a plurality of conductive materials 112-1A, 112-2A, 114-1A, 114-2A and a plurality of insulating materials 116-1A, 116-2A, 116-3A are alternately formed over a carrier substrate C. Adhesion materials 118 are optionally formed between the insulating materials 116-1A, 116-2A, 116-3A and the conductive materials 112-1A, 112-2A, 114-1A, 114-2A, respectively. The material and the formation of the conductive materials 112-1A, 112-2A, 114-1A, 114-2A, the insulating materials 116-1A, 116-2A, 116-3A and the adhesion materials 118 are similar to those of the conductive materials 112A, 114A, the insulating material 116A and the adhesion materials 118 described in FIG. 7A, so the detailed description thereof is omitted herein.

Referring to FIG. 8B, a stack of the conductive materials 112-1A, 114-1A, 112-2A, 114-2A and the insulating materials 116-1A, 116-2A, 116-3A is patterned, to form a needle structure 110. In some embodiments, a stack of the conductive materials 112-1A, 114-1A, 112-2A, 114-2A, the insulating materials 116-1A, 116-2A, 116-3A and the adhesion materials 118A is patterned by using a lithography process with a mask, to form the needle structure 110. The needle structure 110 may include a force needle 112-1, an insulating layer 116-1, a force needle 112-2, an insulating layer 116-2, a sense needle 114-1, an insulating layer 116-3 and a sense needle 114-1 and optional adhesion layers 118 disposed between the insulating layer 116-1, 116-2, 116-3 and the force needle 112-1, 112-2 and between the insulating layer 116-1, 116-2, 116-3 and the sense needle 114-1, 114-2.

Referring to FIG. 8C, the needle structure 110 is removed from the carrier substrate C. For example, the needle structure 110 is detached from the carrier substrate C by any suitable process. Then, the needle structure 110 is assembled with the mounting assembly 140 by placing/inserting the needle structure 110 into the openings 146a, 148a of the first housing element 146 and the second housing element 148, to form a probe head. After that, the assembled structure is then attached to the first wiring substrate 120 and the second wiring substrate 130, to form the probe card 100 of FIG. 4A. In some embodiments, the needle structure 110 and the probe card 100 are similar to those described in FIG. 4A, so the detailed description thereof is omitted herein.

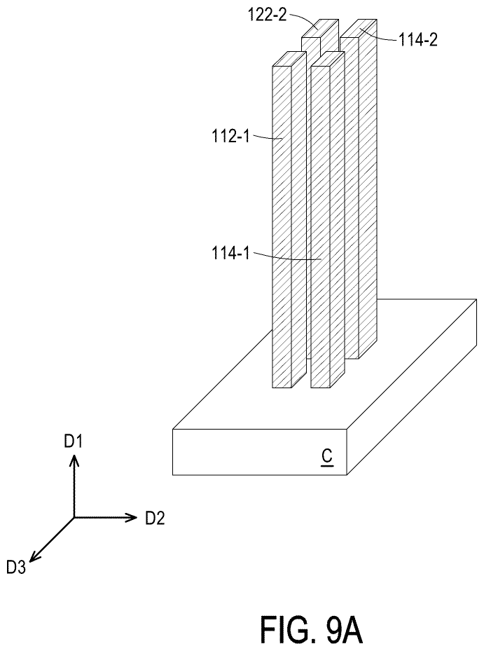

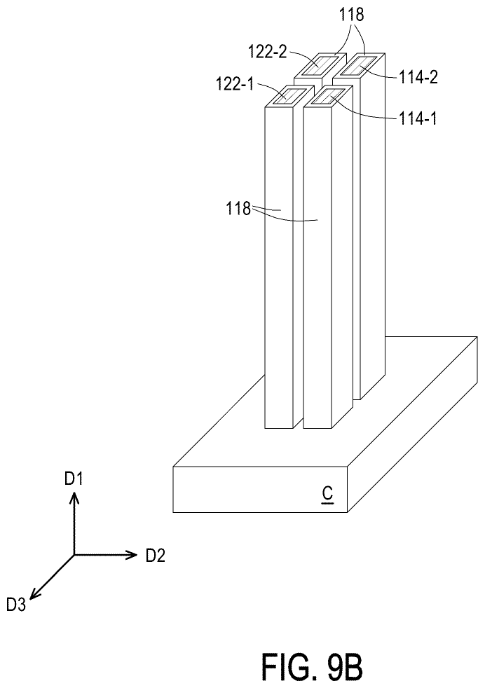

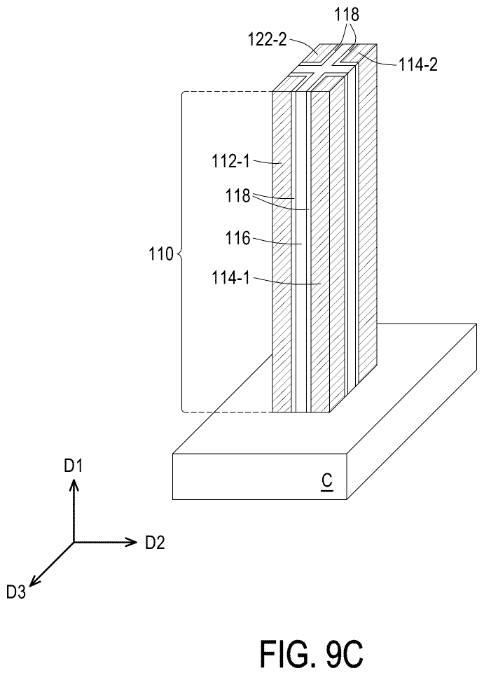

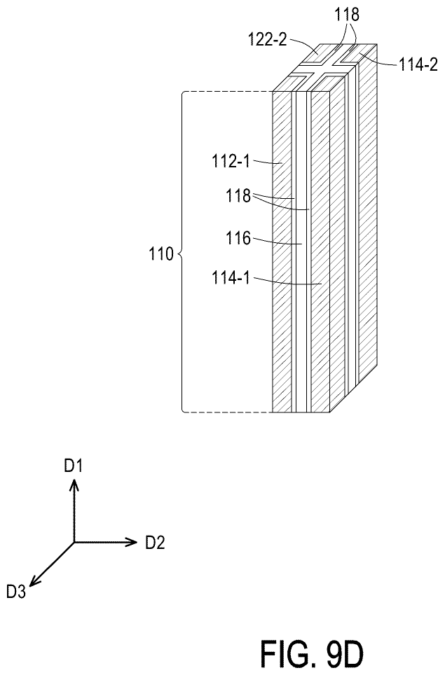

FIG. 9A to FIG. 9D illustrate various cross-sectional views of a method of forming a needle structure according to some embodiments.

Referring to FIG. 9A, force needles 112-1, 112-2 and sense needles 114-1, 114-2 are formed over a carrier C. For example, a conductive material (not shown) of the force needles 112-1, 112-2 and the sense needles 114-1, 114-2 is formed over the carrier C. Then, portions of the conductive material are removed by a lithography process, to form a plurality of force needles 112 and sense needles 114 vertically extending on the carrier C and an opening OP among the force needles 112-1, 112-2 and sense needles 114-1, 114-2. In some embodiments, the force needles 112 and sense needles 114 are pillar-shaped patterns, and the opening OP is cross-shaped.

Referring to FIG. 9B, an adhesion material 118A is formed to surround the force needles 112-1, 112-2 and sense needles 114-1, 114-2. The material and the formation of the adhesion material 118A are similar to those of the adhesion layers 118 described in FIG. 7A, so the detailed description thereof is omitted herein. For example, the adhesion material 118A is formed by a deposition process such an ALD process. In some embodiments, the adhesion material 118A is conformally formed on sidewall surfaces of the force needles 112-1, 112-2 and sense needles 114-1, 114-2 without filling up the opening OP among the force needles 112-1, 112-2 and sense needles 114-1, 114-2.

Referring to FIG. 9C, an insulating layer 116 is formed among the force needles 112-1, 112-2 and sense needles 114-1, 114-2, to form a needle structure 110. For example, an insulating material of the insulating layer 116 is formed over the carrier C to fill up the opening OP among the force needles 112-1, 112-2 and sense needles 114-1, 114-2. Then, portions of the insulating material outside the opening are removed, to form the insulating layer 116. In some embodiments, portions of the adhesion material 118A outside the opening OP are also removed, to form adhesion layers 118 separated from one another.

Referring to FIG. 9D, the needle structure 110 is removed from the carrier substrate C. For example, the needle structure 110 is detached from the carrier substrate C by any suitable process. Then, the needle structure 110 is assembled with the mounting assembly 140 by placing/inserting the needle structure 110 into the openings 146a, 148a of the first housing element 146 and the second housing element 148, to form a probe head. After that, the assembled structure is then attached to the first wiring substrate 120 and the second wiring substrate 130, to form the probe card 100 of FIG. 6A. In some embodiments, the needle structure 110 and the probe card 100 are similar to those described in FIG. 6A and FIG. 6B, so the detailed description thereof is omitted herein. In some embodiments, the force needles 112-1, 112-2 and sense needles 114-1, 114-2 are formed prior to the insulating layer 116. However, the disclosure is not limited thereto.

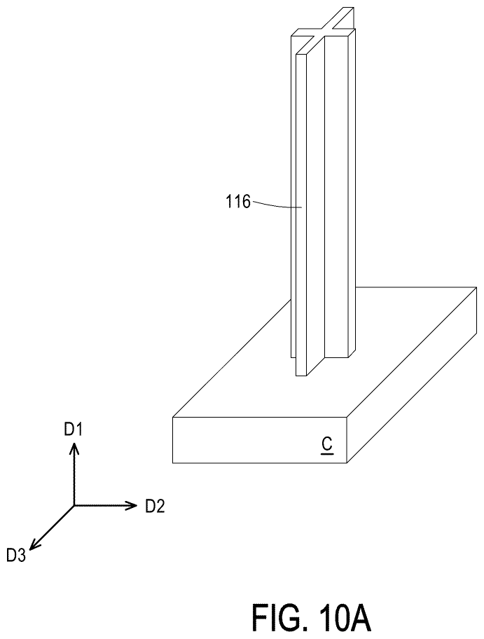

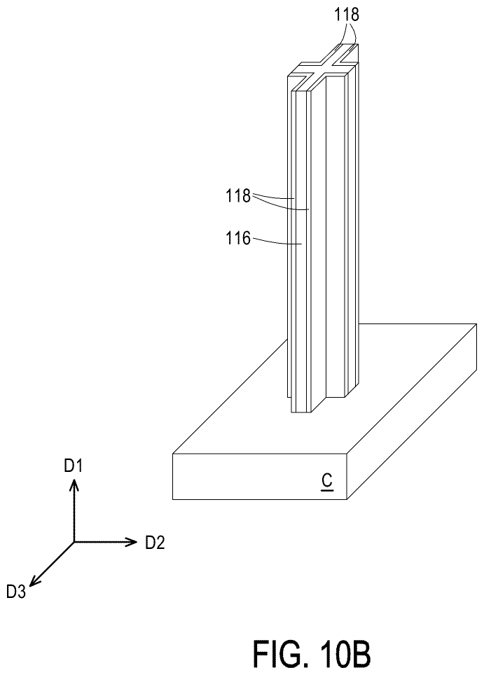

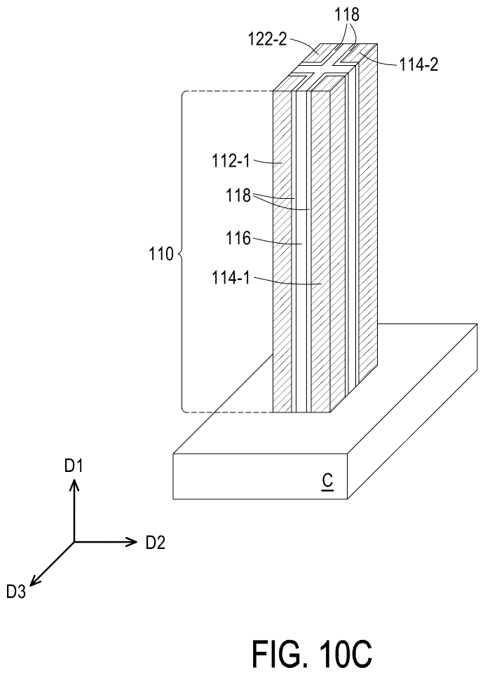

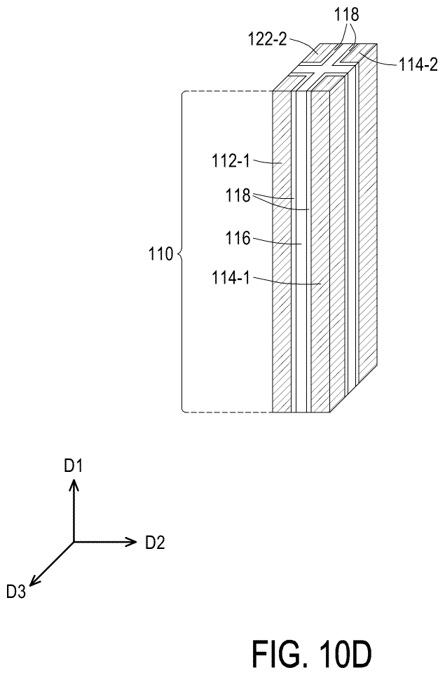

FIG. 10A to FIG. 10D illustrate various cross-sectional views of a method of forming a needle structure according to some embodiments.

Referring to FIG. 10A, a cross-shaped insulating layer 116 is first formed over a carrier C by a patterning process. For example, an insulating material is formed over the carrier C. Then, the insulating material is patterned to the cross-shaped insulating layer 116. The insulating material may include silicon oxide or aluminum oxide; nitrides such as silicon nitride; carbides such as silicon carbide; a combination thereof such as silicon oxynitride, silicon oxycarbide, silicon carbonitride, silicon oxycarbonitride; or the like, and the insulating material may be formed by CVD, ALD, PVD, the like, or combinations thereof.

Referring to FIG. 10B, an adhesive layer 118 is formed on surfaces of the cross-shaped insulating layer 116. An adhesive material is conformally formed on side surfaces of the cross-shaped insulating layer 116, to form the adhesive layer 118. The adhesion material may include a metal such as Pt, Au, Cr, Ti, Al, Ni, W, an alloy thereof or the like, and the adhesion material may be formed by CVD, ALD, PVD, an electro-chemical plating process, the like, or combinations thereof. In alternative embodiments, the adhesive layer 118 may further cover end portions of the cross-shaped insulating layer 116. In such embodiments, the adhesive layer 118 surrounds the insulating layer 116.

Referring to FIG. 10C, force needles 112-1, 112-2 and sense needles 114-1, 114-2 are formed, to form a needle structure 110. For example, conductive materials are formed aside the cross-shaped insulating layer 116 by a deposition process and a lithography process, to form the force needles 112-1, 112-2 and sense needles 114-1, 114-2. The conductive materials may include a metal such as Cu, Pd, Rh and Ag, an alloy thereof or the like, and the conductive materials may be formed by CVD, ALD, PVD, an electro-chemical plating process, the like, or combinations thereof.

Referring to FIG. 10D, the needle structure 110 is removed from the carrier substrate C. For example, the needle structure 110 is detached from the carrier substrate C by any suitable process. In other words, the needle structure 110 may be formed by any suitable process and then assembled with the mounting assembly 140 to form a probe head.

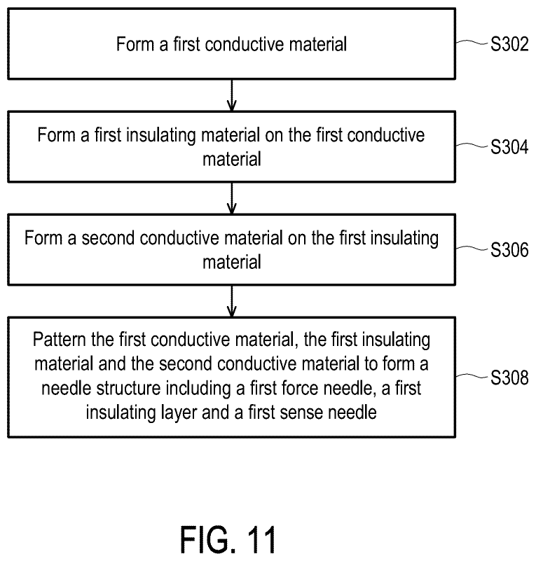

FIG. 11 illustrates a flowchart of a method of forming a semiconductor device according to some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act S302, a first conductive material is formed. FIG. 7A and FIG. 8A illustrate views corresponding to some embodiments of act S302.

A At act S304, a first insulating material is formed on the first conductive material. FIG. 7A and FIG. 8A illustrate views corresponding to some embodiments of act S304.

At act S306, a second conductive material is formed on the first insulating material. FIG. 7A and FIG. 8A illustrate views corresponding to some embodiments of act S306.

At act S308, the first conductive material, the first insulating material and the second conductive material are patterned to form a needle structure including a first force needle, a first insulating layer and a first sense needle. FIG. 7B and FIG. 8B illustrate views corresponding to some embodiments of act S308.

In accordance with some embodiments of the disclosure, a probe card includes a force line, a sense line, a force pad, a sense pad and a needle structure. The force pad and the sense pad are electrically connected to the force line and the sense line respectively, wherein the force pad and the sense pad are electrically isolated. The needle structure includes a force needle, a sense needle and an insulating layer. The force needle is electrically connected to the force pad. The sense needle is electrically connected to the sense pad. The insulating layer is disposed between and electrically isolates the force needle and the sense needle.

In accordance with some embodiments of the disclosure, a probe card includes a plurality of force lines, a plurality of sense lines, a plurality of force pads, a plurality of sense pads and a needle structure. The force pads and the sense pads are electrically connected to the force lines and the sense lines respectively, wherein the force pads and the sense pads are physically separated. The needle structure includes a plurality of force needles, a plurality of sense needles and at least one insulating layer. The force needles are electrically connected to the force pads respectively. The sense needles are electrically connected to the sense pads respectively. The at least one insulating layer is disposed between and electrically isolates the force needles and the sense needles.

In accordance with some embodiments of the disclosure, a method of forming a probe card includes the following steps. A first conductive material is formed. A first insulating material is formed on the first conductive material. A second conductive material is formed on the first insulating material. The first conductive material, the first insulating material and the second conductive material are patterned to form a needle structure including a first force needle, a first insulating layer and a first sense needle.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A probe card, comprising:
a force line and a sense line;
a force pad and a sense pad, electrically connected to the force line and the sense line respectively, wherein the force pad and the sense pad are electrically isolated;
a needle structure, comprising:
a force needle, electrically connected to the force pad;
a sense needle, electrically connected to the sense pad; and
an insulating layer, wherein the insulating layer is disposed between and electrically isolates the force needle and the sense needle.

2. The probe card of claim 1, wherein a shape of the force pad and the sense pad is a polygon, a circle or a combination thereof.

3. The probe card of claim 1, further comprising:
a first wiring substrate; and
a second wiring substrate, wherein the second wiring substrate is disposed between the first wiring substrate and the needle structure, and the second wiring substrate and the first wiring substrate comprise the force line and the sense line therein.

4. The probe card of claim 3, wherein the second wiring substrate has a first surface facing the first wiring substrate and a second surface facing the needle structure, and the force pad and the sense pad are disposed on the second surface.

5. The probe card of claim 3, further comprising:
a jig, attached to the first wiring substrate to surround the second wiring substrate;
a spacer, assembled with the jig, wherein the second wiring substrate is disposed between the first wiring substrate and the spacer; and
a first housing element and a second housing element, disposed on opposite sides of the spacer and holding the needle structure.

6. The probe card of claim 1, wherein the needle structure further comprises an adhered layer disposed between the insulating layer and at least one of the force needle and the sense needle.

7. The probe card of claim 1, wherein first surfaces of the force needle, the sense needle and the insulating layer are substantially coplanar, and second surfaces opposite to the first surfaces of the force needle, the sense needle and the insulating layer are substantially coplanar.

8. The probe card of claim 7, wherein the first surface of the force needle is in direct contact with the force pad and the first surface of the sense needle is in direct contact with the sense pad.

9. The probe card of claim 1, wherein the needle structure is fork-shaped.

10. The probe card of claim 9, wherein first surfaces of the force needle, the sense needle and the insulating layer face the force pad and the sense pad, second surfaces of the force needle, the sense needle and the insulating layer are opposite to the first surfaces, and the first surface of the insulating layer is disposed between the first surfaces of the force needle and the sense needle and the second surfaces of the force needle and the sense needle.

11. A probe card, comprising:
a plurality of force lines and a plurality of sense lines;
a plurality of force pads and a plurality of sense pads, electrically connected to the force lines and the sense lines respectively, wherein the force pads and the sense pads are physically separated; and
a needle structure, comprising:
a plurality of force needles, electrically connected to the force pads respectively;
a plurality of sense needles, electrically connected to the sense pads respectively; and
at least one insulating layer, wherein the at least one insulating layer is disposed between and electrically isolates the force needles and the sense needles.

12. The probe card of claim 11, wherein the at least one insulating layer comprises a plurality of insulating layers, the force needles and the sense needles extend along a first direction, and the force needles and the sense needles are arranged and interleaved by the insulating layers along a second direction substantially perpendicular to the first direction.

13. The probe card of claim 11, wherein the at least one insulating layer is cross-shaped in a top view and separates each two of the force needles and the sense needles.

14. The probe card of claim 11, wherein first surfaces of the force needles, the sense needles and the at least one insulating layer are substantially coplanar, and second surfaces opposite to the first surfaces of the force needles, the sense needles and the at least one insulating layer are substantially coplanar.

15. The probe card of claim 14, wherein the at least one insulating layer includes a surface of facing the force pads and the sense pads, and the force needles and the sense needles comprise portions extended beyond the surface of the at least one insulating layer.

16. The probe card of claim 11, further comprising:
a first wiring substrate; and
a second wiring substrate, wherein the second wiring substrate is disposed between the first wiring substrate and the needle structure, and the force lines and the sense lines are disposed in the second wiring substrate and the first wiring substrate.

17. The probe card of claim 15, wherein the second wiring substrate has a first surface facing the first wiring substrate and a second surface facing the needle structure, and the force pads and the sense pads are disposed on the second surface.

18. A method of forming a probe card, comprising:
forming a first conductive material;
forming a first insulating material on the first conductive material;
forming a second conductive material on the first insulating material; and
patterning the first conductive material, the first insulating material and the second conductive material to form a needle structure including a first force needle, a first insulating layer and a first sense needle.

19. The method of claim 18, wherein forming the needle structure further comprises:
forming a second insulating material on the second conductive material;
forming a third conductive material on the second insulating material;
forming a third insulating material on the third conductive material;
forming a fourth conductive material on the third insulating material; and
patterning the first to fourth conductive materials and the first to third insulating materials, to form the needle structure including the first force needle, the first sense needle, the first insulating layer, a second force needle, a second sense needle and second and third insulating layers.

20. The method of claim 18, wherein forming the needle structure further comprises:
forming an adhesion material between the first insulating material and at least one of the first conductive material and the second conductive material; and
patterning the first conductive material, the first insulating material, the second conductive material and the adhesion material, to form the needle structure including the first force needle, the first insulating layer, the first sense needle and the adhesion layer.
